(19) United States
(12) Patent Application Publication
(10) Pub. No.: US 2011/0255249 A1
(43) Pub. Date: Oct. 20, 2011

(54) HIGH DENSITY FLEXIBLE FOLDABLE INTERCONNECT

(75) Inventors: Warren Lee, Niskayuna, NY (US); Douglas Glenn Wildes, Ballston Lake, NY (US); Svein Bergstoel, Sandefjord (NO)

(73) Assignee: GENERAL ELECTRIC COMPANY, SCHENECTADY, NY (US)

(21) Appl. No.: 12/763,391

(22) Filed: Apr. 20, 2010

(51) Int. Cl. H05K 1/02

(52) U.S. Cl. 361/749

(57) ABSTRACT

A flexible interconnect circuit includes a plurality of substantially flat flex circuits. Each flex circuit has a length substantially greater than its corresponding width. The plurality of flex circuits are folded parallel to their long axes and configured together to provide a layered flex interconnect circuit structure in which at least one ground flex circuit is interposed with one or more signal flex circuits.

### BACKGROUND

The invention relates generally to flexible circuits. In particular, the invention relates to a high density, flexible, foldable interconnect circuit that is particularly suited for applications requiring long, compact interconnect assemblies such as catheters and endoscopes.

Processes for assembling a catheter interconnect presently require that an interconnect stack be assembled from individual signal and ground (GND) layers, e.g., 4 signal layers and 5 GND layers arranged in an alternating fashion. Each signal layer must be separated and unfolded from a panel containing many signal layers in a serpentine shape such as depicted in FIG. 1 that illustrates a flex circuit structure 10 known in the art. The GND layers are cut to length from a spool. The interconnect assembly process requires careful attention to ensure that the layers remain in order and do not become twisted. Further, since each of the signal layers contains termination sites, they must be exactly aligned to their corresponding termination sites, a tedious process that requires differential adjustment of the lengthwise positions of the signal layers relative to one another.

Several of the flexible interconnects depicted in FIG. 1 may be required for arrays requiring a large number of interconnections such as depicted in FIG. 2 that illustrates a flex circuit array structure cross-section 20 known in the art. Each of the flex circuits 24 must therefore be cut from a panel, unfolded, interspersed with ground (GND) layers 22, and assembled into a stack in the correct layered order without any twists, a very tedious, time-consuming process.

A need therefore exists for a simplified high density, flexible, foldable interconnect circuit structure that simplifies assembly of interconnect stacks conventionally assembled from individual signal and GND layers, eliminates twisting generally associated with interconnect stacks assembled from individual signal and GND layers, eliminates layer re-shifting requirements generally necessary during assembly of interconnect stacks assembled from individual signal and GND layers, and substantially reduces the time and expense of assembling interconnect stacks assembled from individual signal and GND layers.

### BRIEF DESCRIPTION

According to one embodiment, a flexible interconnect circuit comprises a plurality of substantially flat flex circuits, each flex circuit having a length substantially greater than its corresponding width, wherein the plurality of substantially flat flex circuits are configured together in a folded parallel to their long axis to provide a layered flex interconnect circuit structure comprising at least one ground flex circuit interposed with one or more signal flex circuits.

According to another embodiment, a flexible interconnect circuit comprises:

one or more signal flex circuits disposed on a first single substantially flat substrate, each signal flex circuit having a length substantially greater its corresponding width;

at least one ground flex circuit disposed on a second single substantially flat substrate, each ground flex circuit having a length substantially greater than its corresponding width;

wherein the one or more signal flex circuits and at least one ground flex circuit are folded parallel to their long axis to provide a layered flex interconnect circuit structure comprising one or more ground flex circuits interposed with one or more signal flex circuits.

### DRAWINGS

These and other features, aspects, and advantages of the present invention will become better understood when the following detailed description is read with reference to the accompanying drawings in which like characters represent like parts throughout the drawings, wherein:

FIG. 1 illustrates a flex circuit structure known in the art;

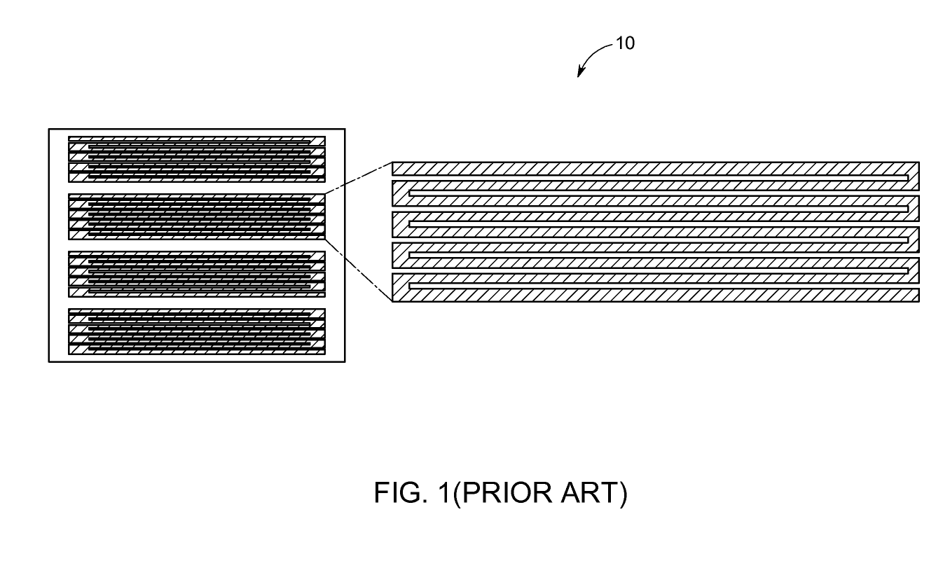

FIG. 2 illustrates a flex circuit array structure known in the art;

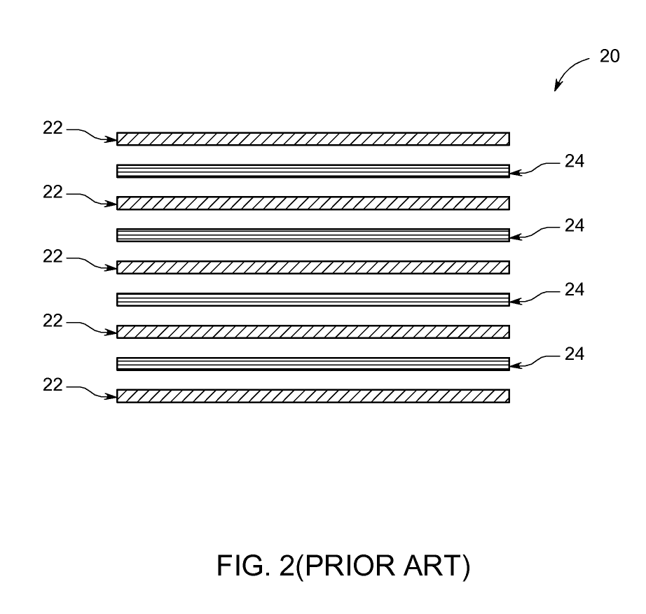

FIG. 3 illustrates a flexible interconnect circuit structure with alternating signal-ground circuits in accordance with one embodiment of the present invention;

FIG. 4 illustrates electrical shield layers added to the flexible interconnect circuit structure depicted in FIG. 3 according to one aspect of the present invention;

FIG. 5 illustrates a flexible interconnect circuit structure with a plurality of flex circuit widths in accordance with another embodiment of the present invention;

FIG. 6 illustrates a flexible interconnect circuit structure configured from distinct and separate flex circuits in accordance with another embodiment of the present invention;

FIG. 7 illustrates a flexible interconnect circuit structure configured with signal flex circuits, ground flex circuits, and ground-shield circuits in accordance with another embodiment of the present invention;

FIG. 8 illustrates a flexible interconnect circuit structure configured with a deflection section according to one embodiment of the present invention;

FIG. 9 illustrates flexible interconnect circuit folding features in accordance with one embodiment of the present invention; and

FIG. 10 illustrates a flexible interconnect circuit structure with a removable section in accordance with another embodiment of the present invention.

While the above-identified drawing figures set forth alternative embodiments, other embodiments of the present invention are also contemplated, as noted in the discussion. In all cases, this disclosure presents illustrated embodiments of the present invention by way of representation and not limitation. Numerous other modifications and embodiments can be devised by those skilled in the art which fall within the scope and spirit of the principles of this invention.

### DETAILED DESCRIPTION

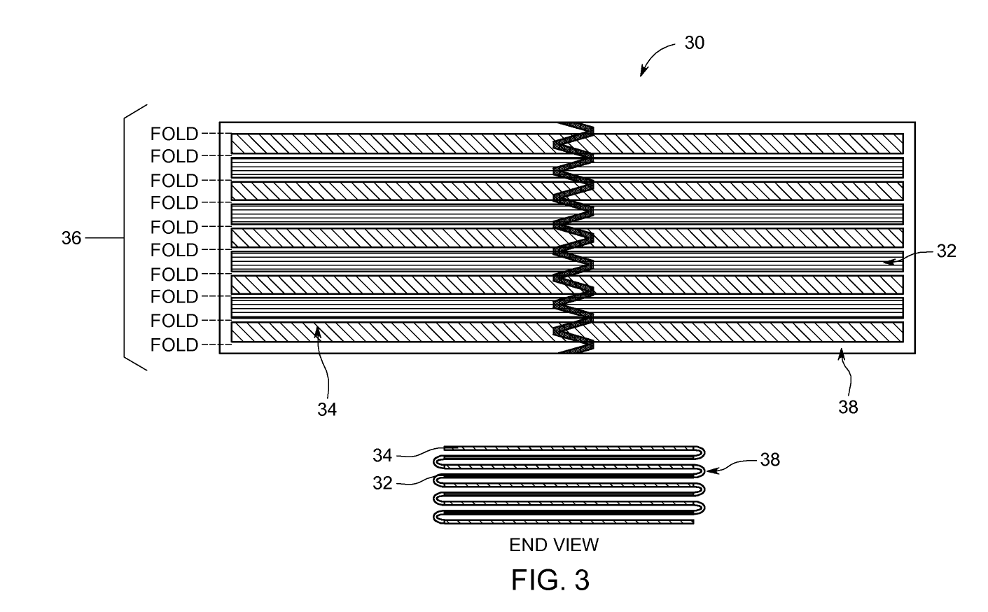

The embodiments described herein with reference to FIGS. 3-9 are directed to structures and processes for constructing a high density, flexible, foldable interconnect circuit that is particularly suited for applications requiring long, compact interconnect assemblies such as catheters and endoscopes. Some embodiments comprise one or more long flex circuits containing adjacent signal and GND segments, such that when folded parallel to their long axis, an alternating signal-GND layered structure is achieved, which is desirable for electrical crosstalk isolation.

The presence of a GND layer between every signal layer is not required however to implement a high density flexible foldable interconnect according to the principles described herein. One embodiment, for example, comprises multiple adjacent signal layers with ground layers only on the outside.

At least one embodiment described herein comprises EMI shielding layers. The interconnect structures can be configured to provide a specific cross-sectional shape subsequent to folding, such as a circle, which is desirable for efficient use of available space in such applications as catheters.

The embodiments described herein greatly simplify the interconnect assembly process, leading to reduced cost, ease of termination of the interconnect ends, and adaptability of the interconnect to a specific shape.

FIG. 3 illustrates a flexible interconnect circuit structure 30 in accordance with one embodiment of the present invention. The flex interconnect circuit structure 30 is fabricated from a single full-length sheet without any serpentine arrangement, and incorporates both signal 32 and GND 34 stripes that may be configured to alternate as shown. When the flexible sheet comprising interconnect circuit structure 30 is folded lengthwise along the dotted lines 36, the desired alternating signal-GND structure is achieved. Cutting out individual signal and GND layers is therefore no longer required, greatly simplifying the assembly process. The corresponding substrate 38 that the flexible interconnect circuit 30 is fabricated on (typically polyimide), may be modified along the lengths where the folds 36 occur, e.g., by perforation or thinning, to ease the folding process.

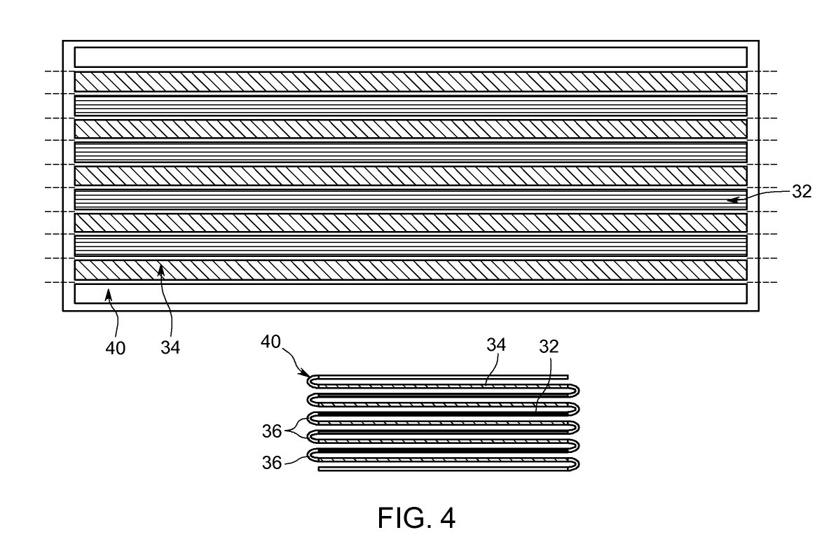

FIG. 4 illustrates electrical shield layers 40 added to the flex interconnect circuit structure 30 depicted in FIG. 3 according to one embodiment of the present invention. These electrical shield layers 40 are added to the signal and ground layers 32, 34 such that when they are folded, the shield layers 40 surround the resultant flex stack comprising the alternating signal and GND flex layers 32, 34. The shield layers 40 may or may not also include the regions where the folds 36 occur, depending upon the desired application.

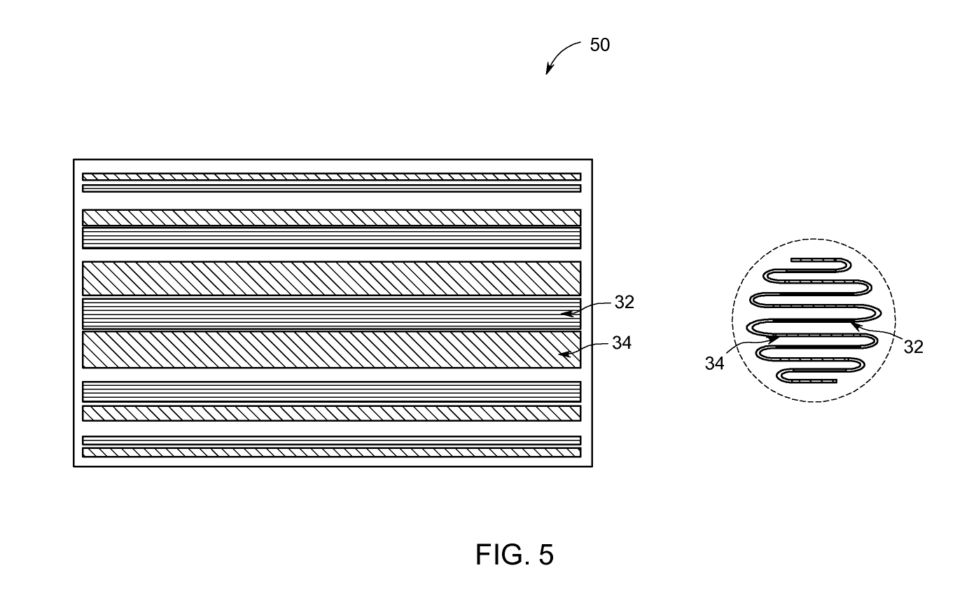

FIG. 5 illustrates a flexible interconnect circuit structure 50 in accordance with another embodiment of the present invention. The signal and GND stripes 32, 34 may have non-uniform widths such that when folded, specific geometries are created. The right side of FIG. 5 illustrates that a circular cross-section is created subsequent to folding which may advantageously utilize a greater percentage of available space for certain application such as catheters or endoscopes.

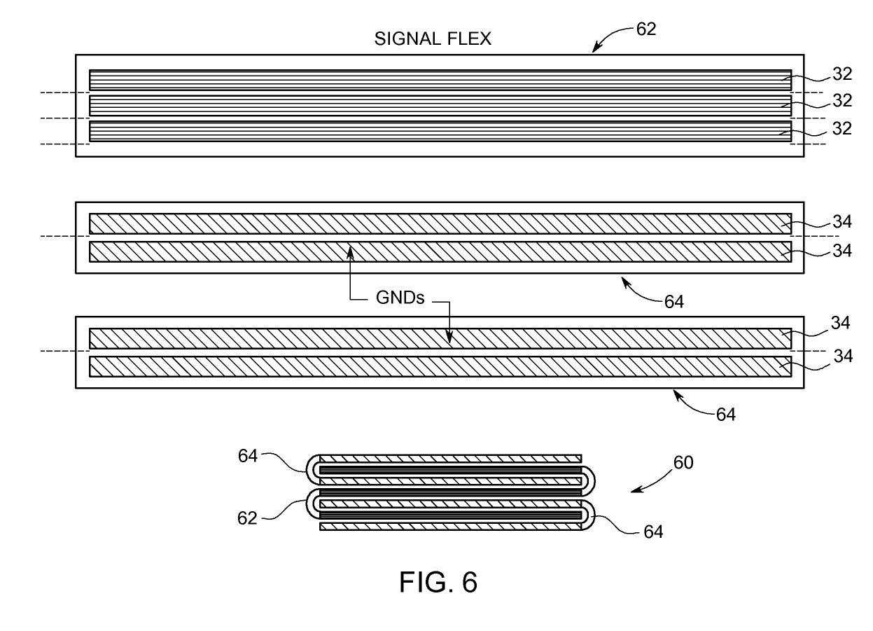

FIG. 6 illustrates a flexible interconnect circuit structure (flex stack) 60 in accordance with another embodiment of the present invention. The flex stack 60 may be assembled from multiple flex circuits. The flex stack 60 depicted in FIG. 6 comprises a single signal flex interconnect structure 62 and two GND flex interconnect structures 64. The signal flex interconnect 62 comprises three signal flex stripes 32 while each GND flex interconnect 64 comprises two GND flex stripes 34. The signal flex interconnect structure 62 is folded in a serpentine fashion. Each GND flex interconnect structure 64 is folded once and then inserted into the spaces between the resultant serpentine structure as shown to form the desired flexible interconnect circuit structure 60.

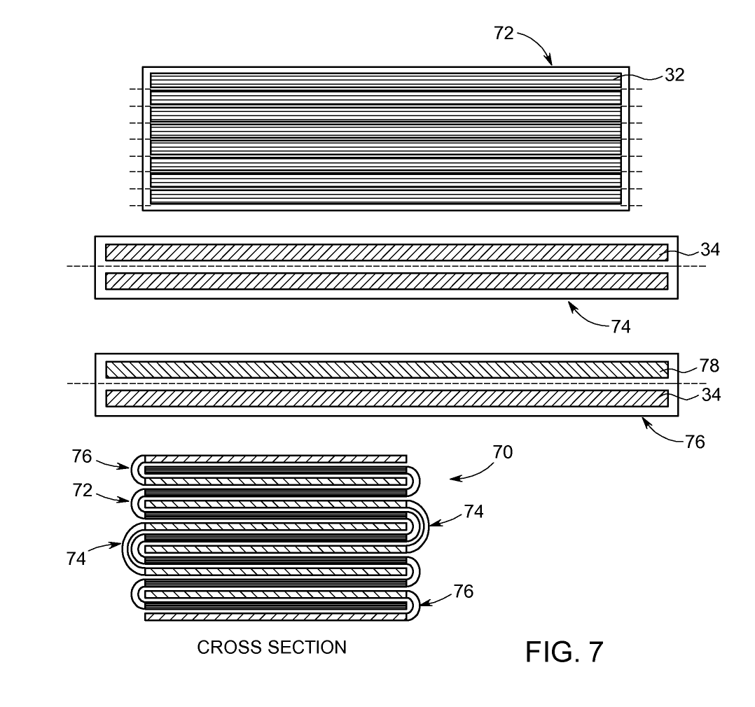

FIG. 7 illustrates a flexible interconnect circuit structure (flex stack) 70 in accordance with another embodiment of the present invention. Flex stack 70 may similarly be assembled from multiple flex circuits. The flex stack 70 depicted in FIG. 7 comprises a single signal flex interconnect structure 72, two GND flex interconnect structures 74, and two GND-shield flex structures 76. The signal flex interconnect 72 comprises seven signal flex stripes 32 while the GND flex interconnect 74 comprises two GND flex stripes 34, and the GND-shield flex structure 76 comprises a GND flex stripe 34 and a shield flex stripe 78. The signal flex interconnect structure 72 is folded in a serpentine fashion. The double GND flex interconnect structure 74 is folded once and then inserted into the spaces between the resultant serpentine structure as shown. The double GND flex interconnect structure 74 may be configured to surround a desired number of signal flex circuits 32. GND flex interconnect structure 74, for example, is configured to surround one pair of signal flex circuits 32. One or more GND-shield flex structures 76 are folded and inserted into the resultant serpentine structure as shown to form the desired flexible interconnect circuit structure 70.

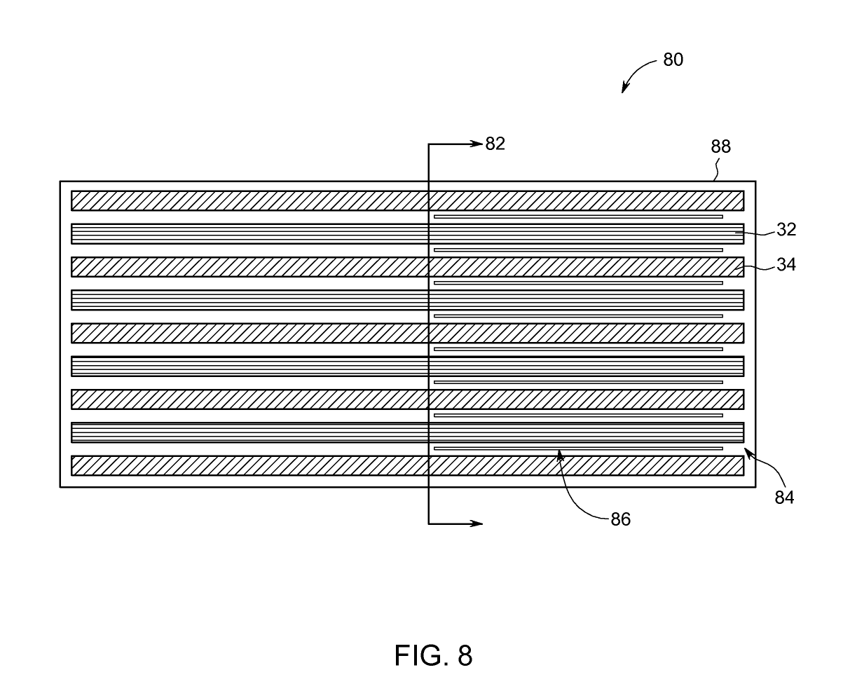

FIG. 8 illustrates a flexible interconnect circuit structure 80 in accordance with another embodiment of the present invention. The base substrate material 88 is perforated or removed in desired portions 86 of one or more deflection sections 82 of the flex interconnect circuit 80 that are most subject to bending. Catheters for example, often require deflection at the tip of the catheter. Removing the substrate 88 between layers in the deflection section 82 would allow the layers 32, 34 to slide relative to one another during deflection. End tabs 84 allow the flex circuits 32, 34 to remain as a single piece during the folding process, but could optionally be later removed from the flex interconnect circuit structure 80 as desired for a particular application.

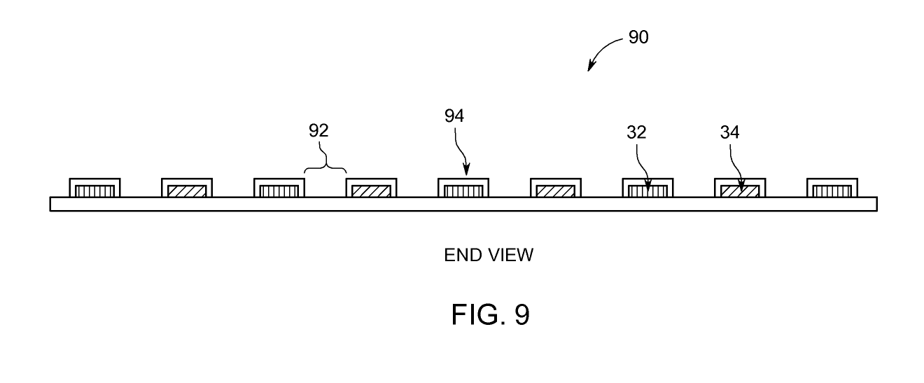

FIG. 9 illustrates flexible interconnect circuit folding features that facilitate easy folding of the flex interconnect circuit where desired, in accordance with one embodiment of the present invention. More specifically, FIG. 9 depicts an end view of a flex interconnect circuit structure 90, where a thinned region 92 is devoid of metal or cover layers 94, signal flex traces 32, and GND flex metal 34, making it easier to fold the flex interconnect circuit 90 along those paths. Other embodiments may employ features including without limitation, one or more of perforations, mechanical scoring, or chemical etching, for example, to facilitate easier folding of the flex interconnect circuit structure 90.

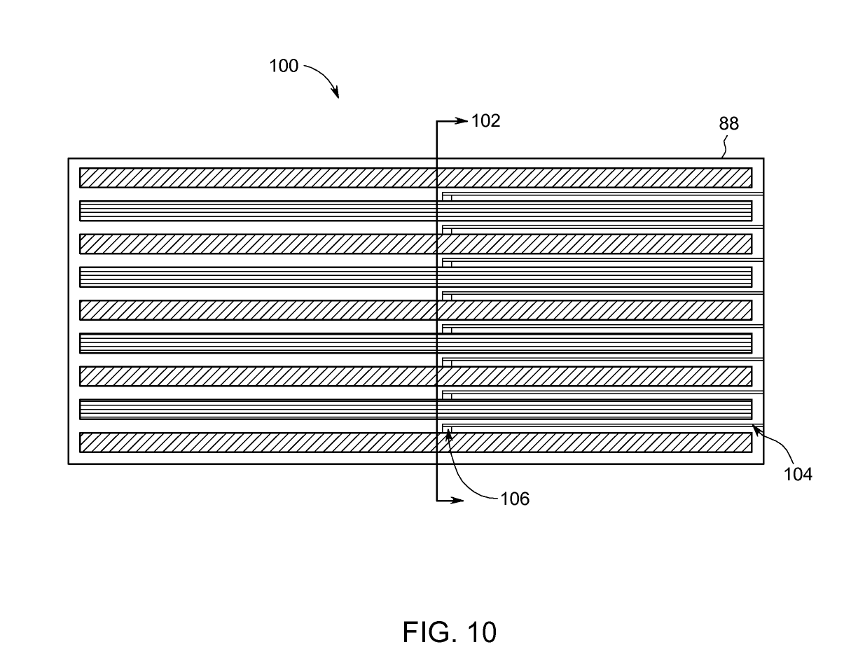

FIG. 10 illustrates a flexible interconnect circuit structure 100 in accordance with another embodiment of the present invention. According to one embodiment, the substrate material 88 employed by flex interconnect circuit structure 100 comprises a removable section 102 that is formed as a tear away strip through use of one or more tear strips 104 and corresponding rip stops 106. According to one embodiment, the tear strip 104 comprises a section of the substrate 88 that is specifically designed to be mechanically weaker than the rest of the substrate 88, e.g., by thinning. The tear strips 104 can be removed once the flex interconnect circuit 100 has been folded in order to provide increased flexibility to a specific portion of the flex interconnect circuit 100, e.g., the deflection section of a catheter. The rip stop 106 terminates the tear strip 104. The rip stop 106 may comprise, for example, a simple through hole.

In summary explanation, structures and processes are described for constructing a high density, flexible, foldable interconnect circuit that is particularly suited for applications requiring long, compact interconnect lengths such as catheters and endoscopes. Particular embodiments comprise one or more long flex circuits containing adjacent signal and GND stripes such that when folded parallel to their long axis, a layered structure comprising signal and GND layers is achieved, which is desirable for electrical crosstalk isolation. The embodiments described herein greatly simplify the interconnect assembly process, leading to reduced cost, ease in termination of the interconnect ends, and adaptability of the interconnect to a specific shape. Other advantages include without limitation, the ability to shield interconnects using the same folded structure, the ability to implement different cross section interconnect stack shapes and elimination or substantial reduction of twisting of flex layers.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A flexible interconnect circuit comprising a plurality of substantially flat flex circuits, each flex circuit having a length substantially greater than its corresponding width, wherein the plurality of substantially flat flex circuits are folded parallel to their long axis to provide a layered flex interconnect circuit structure comprising at least one ground flex circuit interposed with one or more signal flex circuits.

2. The flexible interconnect circuit according to claim 1, wherein each signal flex circuit and each ground flex circuit has a corresponding width such that folding the interconnect circuit parallel to its long axis provides a layered structure comprising a cross sectional interconnect circuit stack shape that is based upon the corresponding widths.

3. The flexible interconnect circuit according to claim 1, wherein the plurality of signal flex circuits are disposed on a first substrate and one or more ground flex circuits are disposed on a different, second substrate.

4. The flexible interconnect circuit according to claim 1, wherein the plurality of signal flex circuits and one or more ground flex circuits are disposed on a single common substrate.

5. The flexible interconnect circuit according to claim 1, further comprising one or more shield flex circuits such that folding the interconnect circuit parallel to its long axis causes the shield flex circuits to surround the plurality of signal flex circuits and the one or more ground flex circuits.

6. The flexible interconnect circuit according to claim 1, wherein the plurality of substantially flat flex circuits are disposed on a single substrate, and further wherein the single substrate comprises a deflection section configured to allow each flex circuit to slide relative to one another during bending.

7. The flexible interconnect circuit according to claim 6, wherein the deflection section comprises a modified substrate region between each pair of flex circuits.

8. The flexible interconnect circuit according to claim 7, wherein the modified substrate region comprises at least one of a perforated substrate material, and the absence of a substrate material.

9. The flexible interconnect circuit according to claim 6, further comprising one or more end tabs configured to maintain structural integrity of flex circuits disposed in the deflection section such that the flex circuits disposed in the deflection section are maintained as a single unit during folding of the flex circuits.

10. The flexible interconnect circuit according to claim 1, further comprising one or more folding paths configured to facilitate folding of the flex circuits.

11. The flexible interconnect circuit according to claim 10, wherein the folding paths comprise at least one of a thinned substrate region devoid of metal or cover layers, a perforated substrate region, a mechanically scored substrate region, and a chemically etched region.

12. A flexible interconnect circuit comprising:
one or more signal flex circuits disposed on a first single substantially flat substrate, each signal flex circuit having a length substantially greater than its corresponding width;
at least one ground flex circuit disposed on a second single substantially flat substrate, each ground flex circuit having a length substantially greater than its corresponding width;
wherein one or more signal flex circuits and at least one ground flex circuit are folded parallel to their long axes and configured together to provide a layered flex interconnect circuit structure comprising one or more ground flex circuits interposed with one or more signal flex circuits.

13. The flexible interconnect circuit according to claim 12, wherein each signal flex circuit and each ground flex circuit has a corresponding width such that folding the interconnect circuit parallel to its long axis provides a layered structure comprising a cross sectional interconnect stack shape that is based upon the corresponding widths.

14. The flexible interconnect circuit according to claim 12, further comprising a deflection section configured to allow the flex circuits to slide relative to one another during bending.

15. The flexible interconnect circuit according to claim 14, wherein the deflection section comprises a modified substrate region between each pair of flex circuits.

16. The flexible interconnect circuit according to claim 15, wherein the modified substrate region comprises at least one of a perforated substrate material, and an absence of substrate material.

17. The flexible interconnect circuit according to claim 16, further comprising one or more end tabs configured to maintain structural integrity of flex circuits disposed in the deflection section such that the flex circuits disposed in the deflection section are maintained as a single unit during folding of the flex circuits.

18. The flexible interconnect circuit according to claim 12, further comprising one or more folding paths configured to facilitate folding of the flex circuits.

19. The flexible interconnect circuit according to claim 18, wherein the one or more folding paths comprise at least one of a thinned substrate region devoid of metal or cover layers, a perforated substrate region, a mechanically scored substrate region, and a chemically etched region.

20. The flexible interconnect circuit according to claim 12, wherein the layered flex circuit structure is configured to provide an alternating signal-ground flex circuit structure.
